(19) United States
(12) Patent Application Publication
(10) Pub. No.: US 2007/0246727 A1
(43) Pub. Date: Oct. 25, 2007

(54) CHIP SEAT STRUCTUER FOR LIGHT-EMITTING CRYSTAL AND A PACKAGING STRUCTURE THEREOF

(76) Inventor: Tsung-Hsin Chen, Jhongpu Township (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/734,837

(22) Filed: Apr. 13, 2007

(30) Foreign Application Priority Data
Apr. 19, 2006 (CN) 200610031510.0

(51) Int. Cl. H01L 33/00

(52) U.S. Cl. 257/99

(57) ABSTRACT

A chip seat structure for light-emitting crystal and a packaging structure thereof. The chip seat structure includes: a model body made of a thermoconductive nonelectroconductive material, the model body having an integrated thermoconductive section; at least one cup seat disposed on a top face of the model body for mounting at least one light-emitting chip therein; and multiple electroconductive layers built on the surfaces of the model body and the cup seat. The electroconductive layers are designed with at least two electroconductive regions respectively defined as a cathode and an anode. At least one electrode-separating line is laid on the surface of the cup seat between the two electroconductive regions as a separating region. A light-emitting chip can be fixed in the cup seat and packaged at high heat-absorbing and heat-dissipating efficiency.

### BACKGROUND OF THE INVENTION

The present invention is related to a chip seat structure for light-emitting crystal. The chip seat is integrally made of a thermoconductive nonelectroconductive material to form a thermoconductive section. The electroconductive layers are respectively built on the thermoconductive section by means of electroplating, coating, deposition, printing, inlay, attachment, etc. The electroconductive layers serve as the cathode and anode without breaking the chip seat apart. In addition, the light-emitting chips are fixed on the chip seat and packaged at high heat-absorbing and heat-dissipating efficiency.

Light-emitting diodes (LED) have been widely applied to various fields such as electronic products, information products, outdoor advertisement signs, traffic signs, etc. In a conventional LED, a semiconductor chip is fixed on a frame as a light source. The frame is made by punching and is electroplated with a silver coating. Two terminals of a lead are respectively connected to the frame and the chip. Epoxy is poured onto an upper section of the frame to form a transparent body for packaging the chip and the lead. When emitting light, the chip generates heat. In case the heat is not dissipated, the chip will be damaged due to overheating. A part of the heat accumulates in the transparent body, while another part of the heat is dissipated through the first and second contact pins of the frame. However, the transparent body is made of epoxy which has poor thermoconductivity. Therefore, most of the heat generated by the chip accumulates in the transparent body and is not effectively dissipated. Simply the contact pins of the frame can conduct the heat to dissipate at low efficiency.

Taiwanese Utility Model Patent Application No. 90201309 discloses an LED bracket having two other contact pins in addition to the original two. Accordingly, the heat generated by the chip can be dissipated through the frame and the four contact pins. Taiwanese Utility Model Patent Application No. 91210274 discloses an LED bracket having a first, a second and a fourth contact pins as the anode and a third elliptic bowl-shaped contact pin as the cathode. Three chips can be rested on the third contact pin to emit different colors of lights. The four contact pins serve to dissipate the heat. However, in practice, such structure can only achieve limited heat-dissipating effect.

It is therefore tried by the applicant to provide a chip seat for light-emitting crystal, which is designed with different structure to widen the application range. In addition, the structure can dissipate the heat at higher efficiency. Also, without enlarging the package volume, the chip seat or the contact pins have larger heat-dissipating area and larger thermoconductive section.

### SUMMARY OF THE INVENTION

It is therefore a primary object of the present invention to provide a chip seat structure for light-emitting crystal and a packaging structure thereof. The chip seat structure has a model body made of a thermoconductive nonelectroconductive material to form an integrated thermoconductive section for dissipating heat at high efficiency. The chip seat further has at least one cup seat disposed on a top face of the model body for mounting at least one light-emitting chip therein. The chip seat also has multiple electroconductive layers built on the surfaces of the model body and the cup seat. The electroconductive layers are designed with at least two electroconductive regions respectively defined as a cathode and an anode. At least one electrode-separating line is laid on the surface of the cup seat between the two electroconductive regions. A light-emitting chip can be fixed in the cup seat by means of glue material by small area and packaged with a photomask of high heat-dissipating efficiency by small range. The present invention can be best understood through the following description and accompanying drawings wherein:

### BRIEF DESCRIPTION OF THE DRAWINGS

FIG. 1 is a sectional view showing the relationship between the thermoconductive section, the electroconductive layers and the chip of the present invention;

FIG. 2 shows the layout of the model body of the present invention with one single chip;

FIG. 3 shows the layout of the model body of the present invention with two chips;

FIG. 4 shows the lay out of the model body of the present invention with three chips;

FIG. 5 is a perspective sectional view of a preferred embodiment of the present invention;

FIG. 6 is a perspective view of another embodiment of the present invention;

FIG. 7 is a perspective view according to FIG. 6, showing the sealing glue of the package;

FIG. 8 is a perspective view of still another embodiment of the present invention;

FIG. 9 is a perspective view of still another embodiment of the present invention, showing the electroconductive layers thereof;

FIG. 10 is a perspective view of still another embodiment of the present invention;

FIG. 11 is a perspective view of still another embodiment of the present invention, showing the electroconductive layers thereof;

FIG. 12 is a perspective partially sectional view of still another embodiment of the present invention;

FIG. 13 is a sectional view of still another embodiment of the present invention, showing the sealing glue of the package structure thereof;

FIG. 14 is a sectional view of still another embodiment of the present invention according to FIG. 13, showing the sealing glue of the package structure thereof;

FIG. 15 is a perspective sectional view of still another embodiment of the present invention;

FIG. 16 is a perspective view of still another embodiment of the present invention, showing that the cavity downward extends from the bottom of the model body by a preset length;

FIG. 17 is a perspective sectional view of still another embodiment of the present invention, showing that the cavity is upward tapered;

FIG. 18 is a perspective sectional view of still another embodiment of the present invention;

FIG. 19 is a perspective sectional view of still another embodiment of the present invention;

FIG. 20 is a top view of still another embodiment of the present invention, showing that the electrode-separating lines are laid out according to different circuit designs;

FIG. 21 is a perspective sectional view of still another embodiment of the present invention, showing that the pit communicates with the cavity;

FIG. 22 is a perspective sectional view of still another embodiment of the present invention, showing that the pit communicates with the cavity;

FIG. 23 is a perspective view of still another embodiment of the present invention, showing that the pit communicates with the cavity;

FIG. 24 is a perspective sectional view of still another embodiment of the present invention, showing that the pit communicates with the cavity;

FIG. 25 is a sectional view of still another embodiment of the present invention, showing that the cup seat is multistepped;

FIG. 26 is a perspective sectional view of still another embodiment of the present invention;

FIG. 27 is a perspective sectional view of still another embodiment of the present invention;

FIG. 28 is a perspective sectional view of still another embodiment of the present invention;

FIG. 29 is a perspective view of still another embodiment of the present invention;

FIG. 30 is a perspective sectional view of still another embodiment of the present invention;

FIG. 30A is a perspective sectional view of still another embodiment of the present invention according to FIG. 30;

FIG. 31 is a perspective view of still another embodiment of the present invention;

FIG. 32 is a perspective view of still another embodiment of the present invention;

FIG. 33 is a perspective sectional view of still another embodiment of the present invention;

FIG. 34 is a perspective sectional, view of stilt another embodiment of the present invention, showing that the bottom face of the model body is formed with several cavities;

FIG. 35 is a perspective sectional view of still another embodiment of the present invention, showing that the surface of the model body is formed with multiple grooves;

FIG. 36 is a perspective sectional view of still another embodiment of the present invention, showing that the central cavity of the bottom face of the model body downward extends by a preset length;

FIG. 36A is a perspective sectional view of still another embodiment of the present invention according to FIG. 36;

FIG. 37 is a perspective sectional view of still another embodiment of the present invention;

FIG. 38 is a perspective sectional view of still another embodiment of the present invention;

FIG. 38A is a perspective sectional view of still another embodiment of the present invention according to FIG. 38;

FIG. 39 is a perspective sectional view of still another embodiment of the present invention, showing that the model body is formed with sockets in which external contact pins can be inserted;

FIG. 40 is a perspective sectional view according to FIG. 39, in which the external contact pins are inserted in the sockets of the model body;

FIG. 41 is a perspective sectional view of still another embodiment of the present invention;

FIG. 42 is a perspective sectional view of still another embodiment of the present invention, showing that the external contact pins are inserted in the sockets of the model body;

FIG. 43 is a perspective view of still another embodiment of the present invention, showing that multiple contact pins are connected with the model body corresponding to the layout of the electroconductive regions of the model body;

FIG. 44 is a perspective sectional view of still another embodiment of the present invention;

FIG. 45 is a perspective sectional view according to FIG. 44, in which the external contact pins are inserted in the sockets of the model body;

FIG. 46 is a perspective sectional view of still another embodiment of the present invention;

FIG. 46A is a perspective sectional view of still another embodiment of the present invention according to FIG. 46;

FIG. 47 is a perspective sectional view of still another embodiment of the present invention, in which the external contact pins are inserted in the sockets of the model body;

FIG. 48 is a perspective sectional view of still another embodiment of the present invention, in which the model body is formed with square sockets in which multiple square contact pins can be inserted;

FIG. 49 is a perspective sectional view according to FIG. 48, in which the square contact pins are inserted in the square sockets of the model body;

FIG. 50 is a perspective sectional view of still another embodiment of the present invention;

FIG. 51 is a perspective view of still another embodiment of the present invention;

FIG. 52 is a perspective view of still another embodiment of the present invention;

FIG. 53 is a perspective sectional view of still another embodiment of the present invention;

FIG. 54 is a perspective view of still another embodiment of the present invention, showing that multiple contact pins are connected with the model body corresponding to the layout of the electroconductive regions of the model body;

FIG. 55 is a perspective sectional view of still another embodiment of the present invention, in which the model body is formed with splined sockets in which multiple splined contact pins can be inserted;

FIG. 56 is a perspective partially sectional view of still another embodiment of the present invention;

FIG. 57 is a perspective view of still another embodiment of the present invention, showing that multiple contact pins are connected with the model body corresponding to the layout of the electroconductive regions of the model body; and

FIG. 58 is a perspective view of still another embodiment of the present invention, showing that multiple cup seats are arranged on a board unit, on which multiple light-emitting chips can be disposed in the cup seats.

### DETAILED DESCRIPTION OF THE PREFERRED EMBODIMENTS

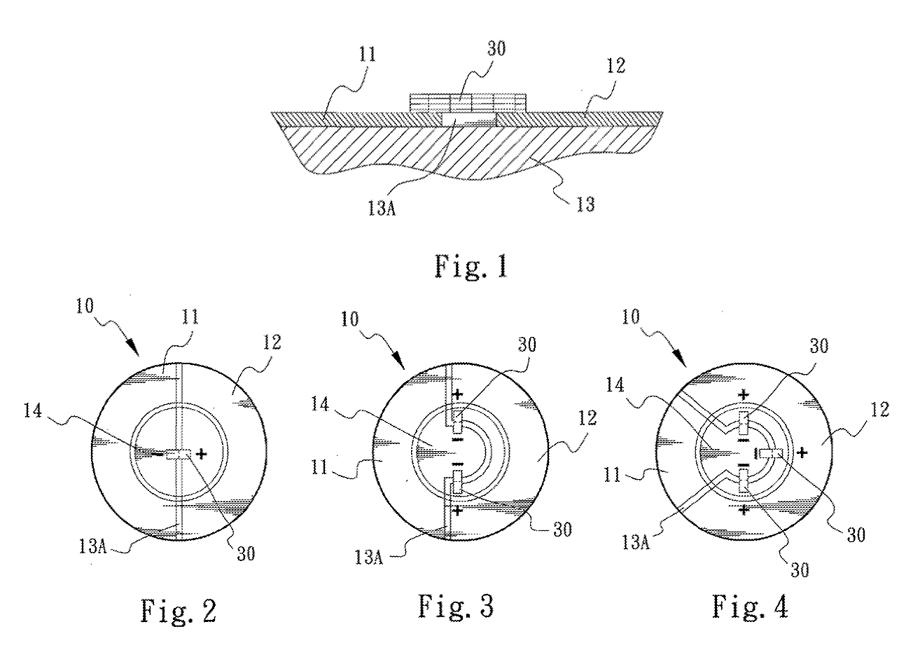

Please refer to FIG. 1. The model body 10 of the present invention is mainly made of a thermoconductive nonelectroconductive material (such as ceramics, silicon or the like) to form a thermoconductive section 13, Multiple electroconductive layers 11, 12 are respectively built on the thermoconductive section 13 to serve as the cathode and anode. An electrode-separating line 13A is laid between the two electroconductive layers 11, 12 according to the specification of the chip 30. Accordingly, the chip 30 can be bridged over the electro-separating line 13A between two electrodes. When powered on, the chip 30 is energized to emit light.

Referring to FIGS. 2 to 4, the electroconductive layers 11, 12 can be laid out in accordance with the number of the chips 30. The electrode-separating line 13A is designed with different textures, depending on the number of the chips 30, Accordingly, the chips 30 can emit light at highest efficiency. For example, as shown in FIG. 2, with respect to one single chip 303 the electrode-separating line 13A extends through a central portion of the surface of the thermoconductive section 13. FIGS. 3 and 4 respectively show the layouts of the regions of the electroconductive layers 11, 12 for two and three chips 30. Accordingly, the layouts of the electrode-separating line 13A are varied.

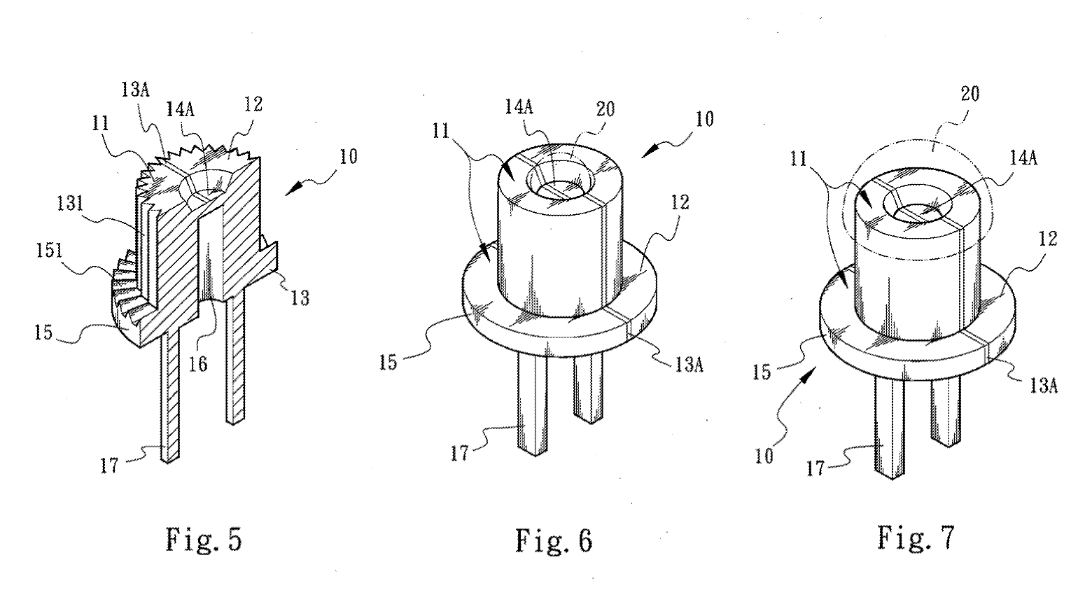

Referring to FIGS. 5 to 7, according to a preferred embodiment, the present invention includes: a model body 10 made of a thermoconductive nonelectroconductive material to form an integrated thermoconductive section 13; and a cup seat 14 disposed on a top face of the model body 10. At least one light-emitting chip 30 is accommodated and mounted in the cup seat 14. The electroconductive layers 11, 12 are built on the surface of the model body 10 and the cup seat 14. At least two electroconductive regions are laid out and defined as the cathode and anode. The electroconductive regions define an electrode-separating line 13A on the surface of the cup seat 14. The width of the electrode-separating line 13A is determined by the size, specification and arrangement of the light-emitting chip 30. Also, as shown in the figures, at least one contact pin 17 is planted in the thermoconductive section 13 of the model body 10. The contact pin 17 serves to increase the heat-radiating area of the model body 10. In addition, the contact pin 17 can be electrically connected with the electroconductive layers 11, 12 for electrically connecting with a mounting circuit.

In a preferred embodiment, the model body 10 is a cylindrical body as a thermoconductive section 13. A lower end of the cylindrical body is formed with a flange section 15 for speeding heat-radiation of the model body 10. This prolongs the using life of the product.

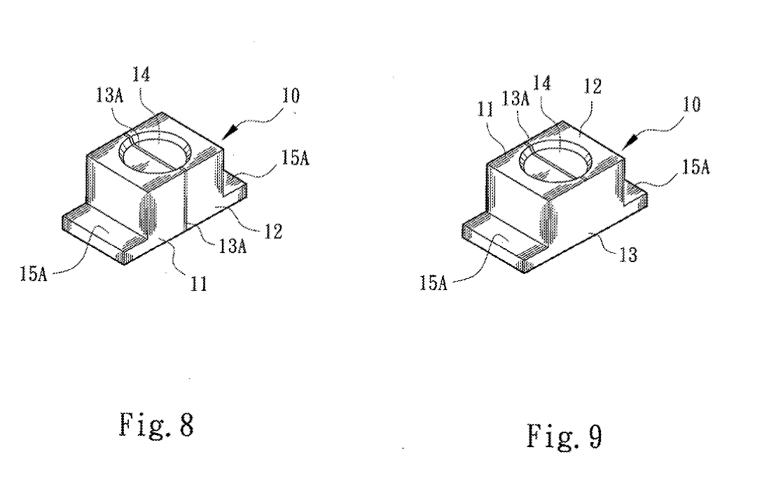

FIG. 8 shows another embodiment of the present invention, in which the model body 10 is substantially a cubic body. Two wing sections 15A laterally extend from the lower ends of two opposite rigid walls of the model body 10 as the thermoconductive section 13. Accordingly, the heat-radiating area of the thermoconductive section 13 is enlarged to enhance the heat-radiating efficiency. The cup seat 14 is disposed on the top face of the model body 10. As shown in FIG. 8, the electrode-separating line 13A is such arranged as to divide the electroconductive layers 11, 12 into two halves of cathode and anode.

Alternatively, the layout of the electrode-separating line 13A can be redesigned. For example, the other two opposite rigid walls free from the wing sections 15A have no electroconductive region. Accordingly, the thermoconductive section 13 can directly contact outer side. Therefore, in use, the heat generated by the chip 30 can be more quickly dissipated as shown in FIG. 9.

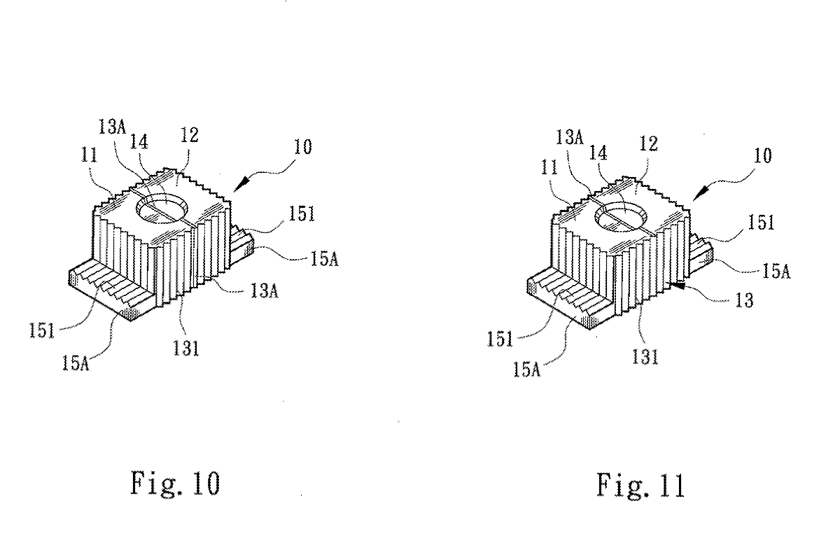

FIGS. 10 and 11 show a modification of the embodiment of FIGS. 8 and 9. The surfaces of the rigid walls and the wing sections 15A of the model body 10 are formed with grooves 131, 151 to enlarge the area of the model body 10 in contact with outer side. This can enhance the heat-radiating efficiency. In addition, the grooved structures 131, 151 serve to enhance the stability when packaged.

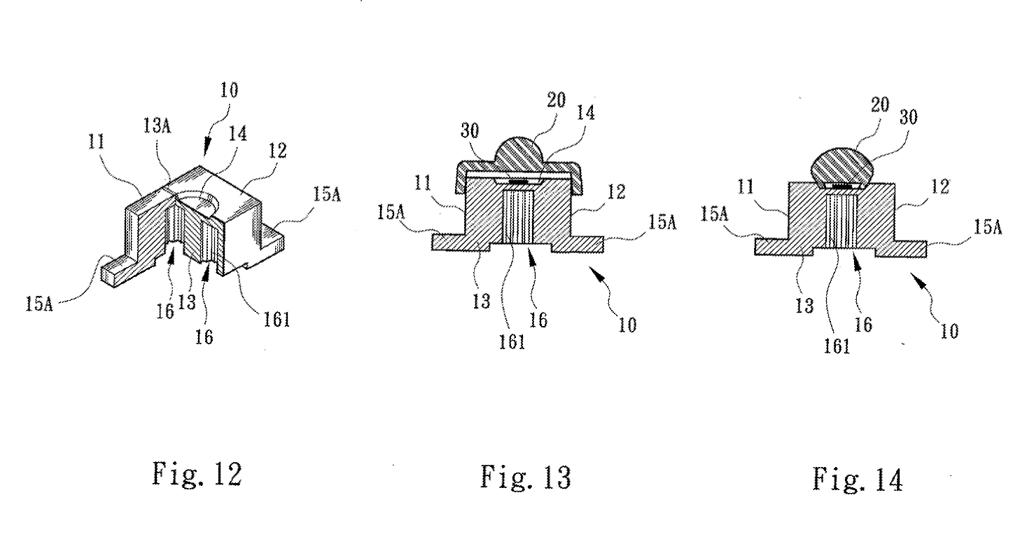

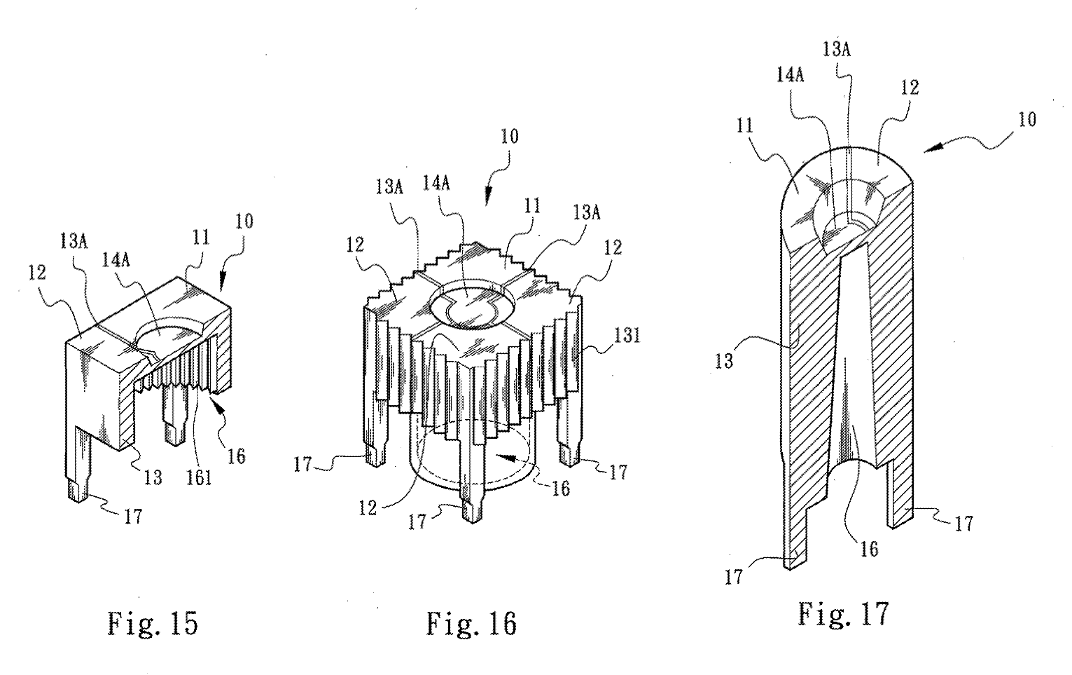

FIGS. 12 to 17 show another modification of the embodiment of FIGS. 8 and 9. As shown in FIG. 12, the bottom of the model body 10 is formed with two cavities 16 upward extending from the bottom face to a position near the top face (under the cup seat 14). The wall faces of the cavities 16 are formed with grooves 161 for enlarging heat-radiating area. Referring to FIGS. 13 and 14, when the chip 30 is powered on to emit light, the generated heat can be more quickly dissipated by means of the cavities 16 under the cup seat 14. In addition, as shown in FIG. 13. The transparent packaging body (photomask) 20 is only partially disposed on the model body 10 near the cup seat 14. In FIG. 14, the transparent packaging body 20 simply occupies the interior of the cup seat 14 so as to minimize the reduction of the heat-radiating area caused by packaging. Accordingly, the heat-dissipating efficiency is enhanced.

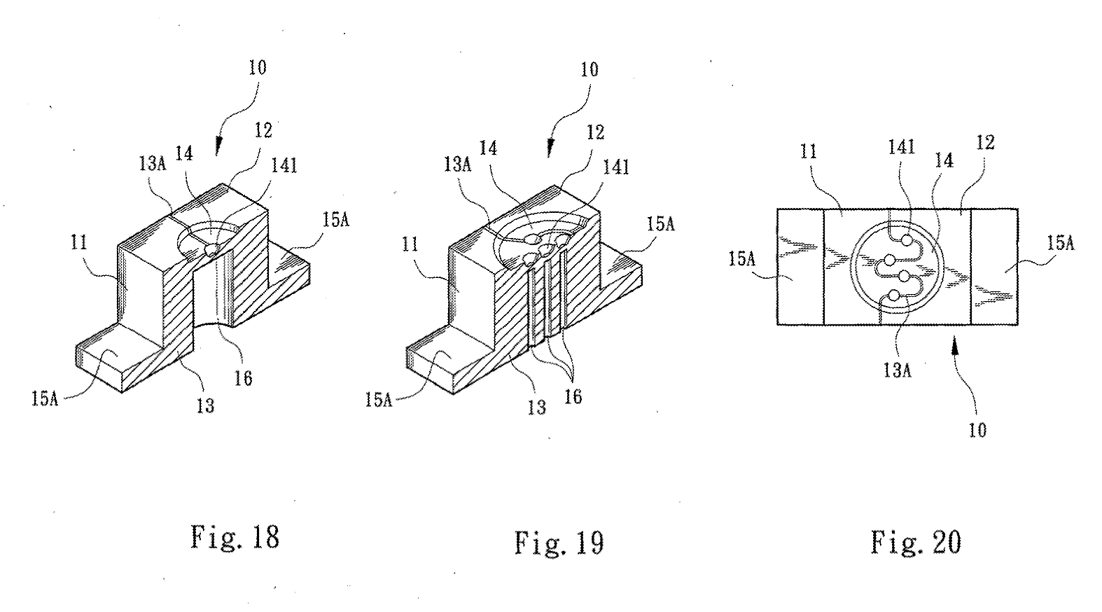

FIGS. 18 to 20 show still another modification of the embodiment of FIGS. 8 and 9. At least one pit 141 is formed at the center of the cup seat 14. The pit 141 can be circular, square, rectangular, rhombic, etc. Little amount of adhesive (such as silver glue, white glue and insulating glue) is directly filled into the pit 141 for adhering one or more chip 30 to the cup seat 14 without loosening or displacement. In addition, the bottom of the chip 30 possibly directly contacts the surface of the cup seat 14 by an area over 30%. Accordingly, the heat generated by the working chip 30 can be directly conducted to the cup seat 14 and dissipated from the entire thermoconductive section 13 at high efficiency. The number of the pits 141 is determined by the number of the chips 30. After the pits 141 are laid out, the electrode-separating line 13A is laid out according to the design of the circuit as shown in FIG. 20.

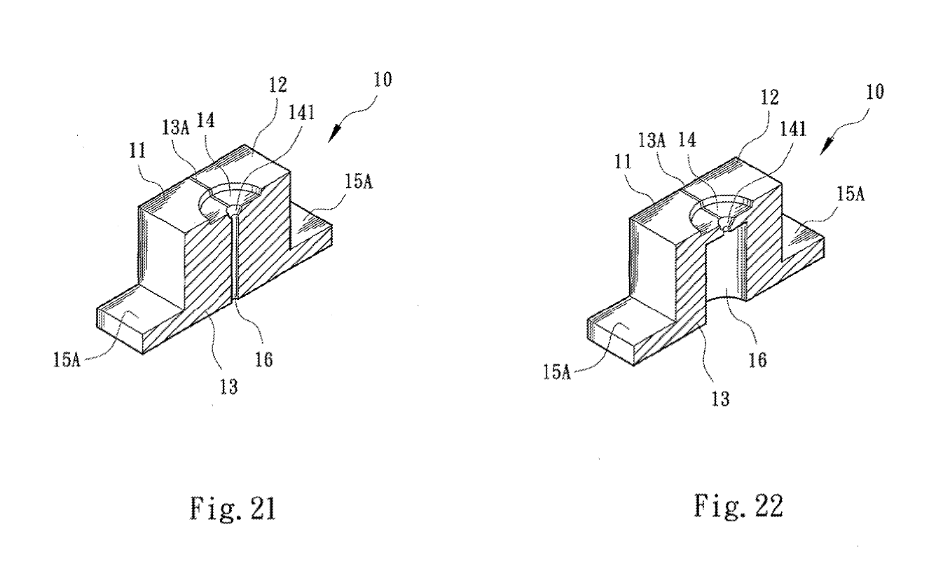

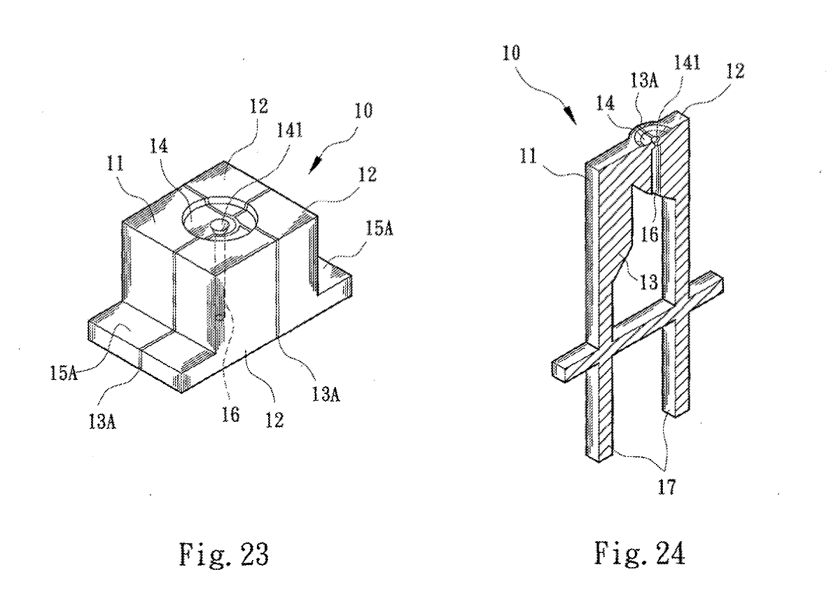

FIGS. 21 to 24 show another modified embodiment according to FIGS. 18 and 19. As shown in FIG. 21, the pit 141 at the center of the cup seat 14 and the cavity 16 under the cup seat 14 communicate with each other. After the chip 30 is adhered to the cup seat 14, the model body 10 is packaged and baked at high temperature for a long time. Under such circumstance, the low-melting-point adhesive is molten into a liquid state to be exhausted from the cavity 16. Accordingly, the pit 141 is open to the outer side. When the chip 30 is powered on to emit light, the heat is immediately dissipated to outer side through the pit 141 and the cavity 16. This also enhances the heat-dissipating efficiency.

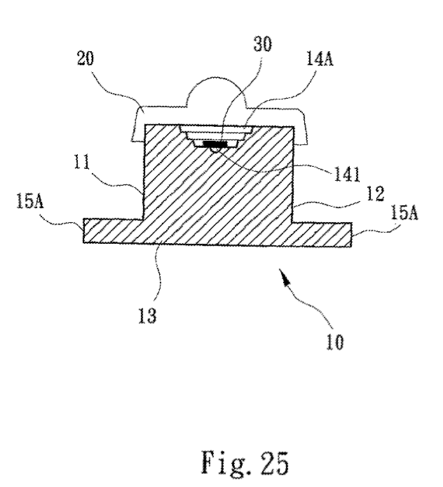

FIG. 25 shows still another embodiment of the present invention, in which the cup seat 14 on the top face of the model body 10 is redesigned to form a multistepped cup seat 14A. The multistepped cup seat 14A serve, to focus the light, high-power refract the light, high-power enlarge the lighting area and high-power enlarge the lighting length. The multistepped cup seat 14A provides a high-power optical effect to enhance the illumination.

According to the above arrangement, the chip seat structure for light-emitting crystal of the present invention includes a thermoconductive section 13 and electroconductive layers 11, 12 built on the thermoconductive section 13. This is different from the conventional technique in which the model body 10 is cut into the cathode and anode. In the conventional technique, the cup seat 14 is disposed on the top face of the cathode of the chip seat. In contrast to the conventional technique, the model body 10 is integrally formed so that there is a larger area for disposing the cup seat 14. Accordingly, with the same volume of chip seat, more light-emitting chips 30 or light-emitting chips 30 with higher powers can be arranged. In addition, with the multistepped cup seat 14A, the golden line for electrical connection can be soldered between the chips 30 and the steps of the multistepped cup seat 14A. This shortens the length of the golden line to reduce the cost. Also, this avoids the problem of fusion in use of high-power chips. Moreover, the conduction and bonding of flip-chip type can be directly employed to obviate the difficulty and inconvenience in soldering the golden line.

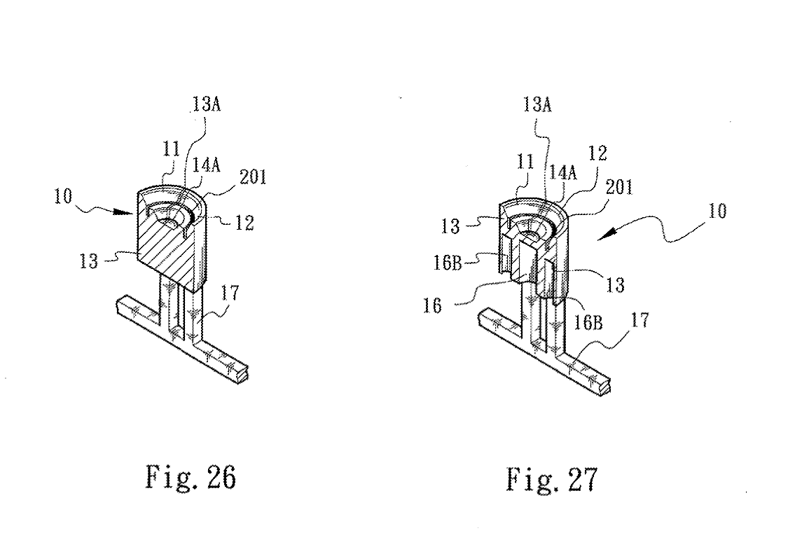

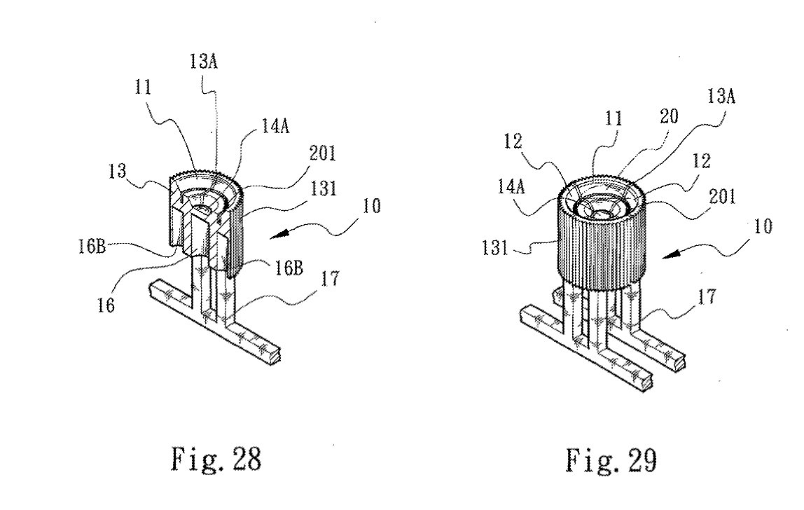

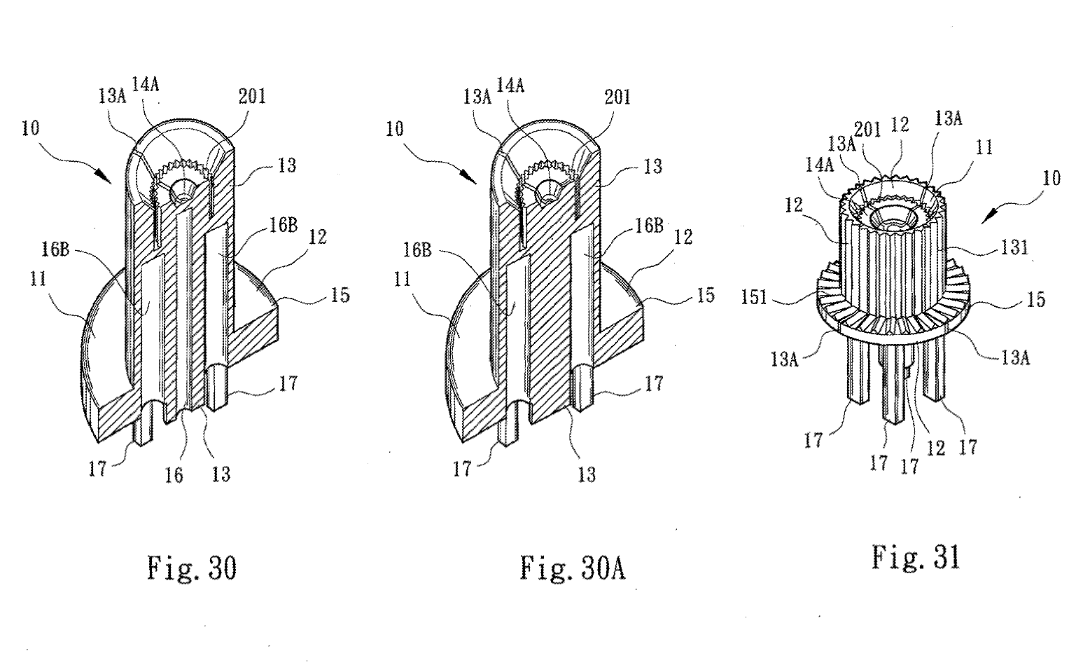

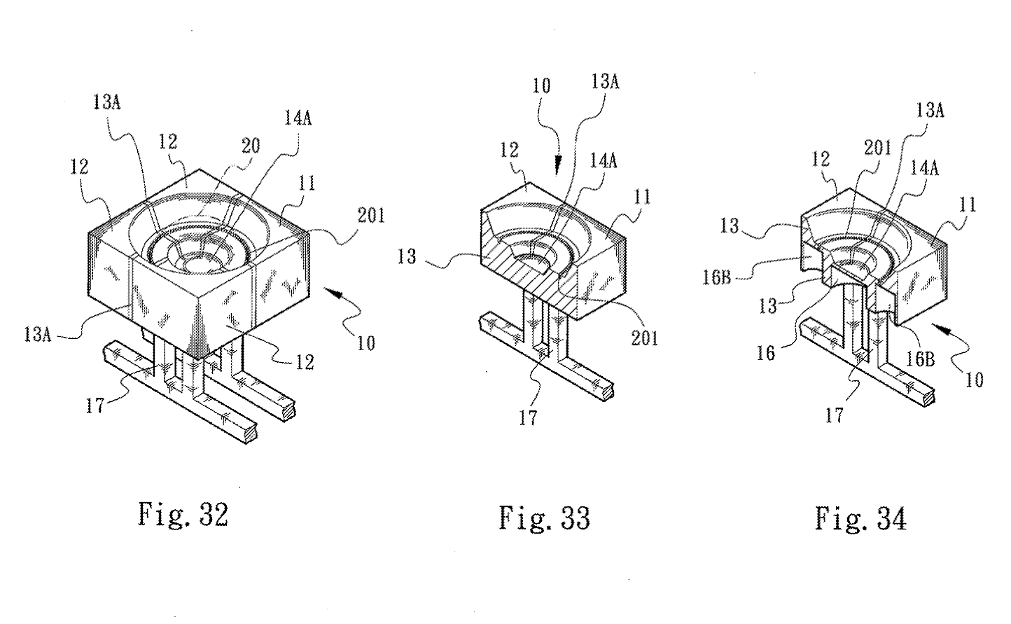

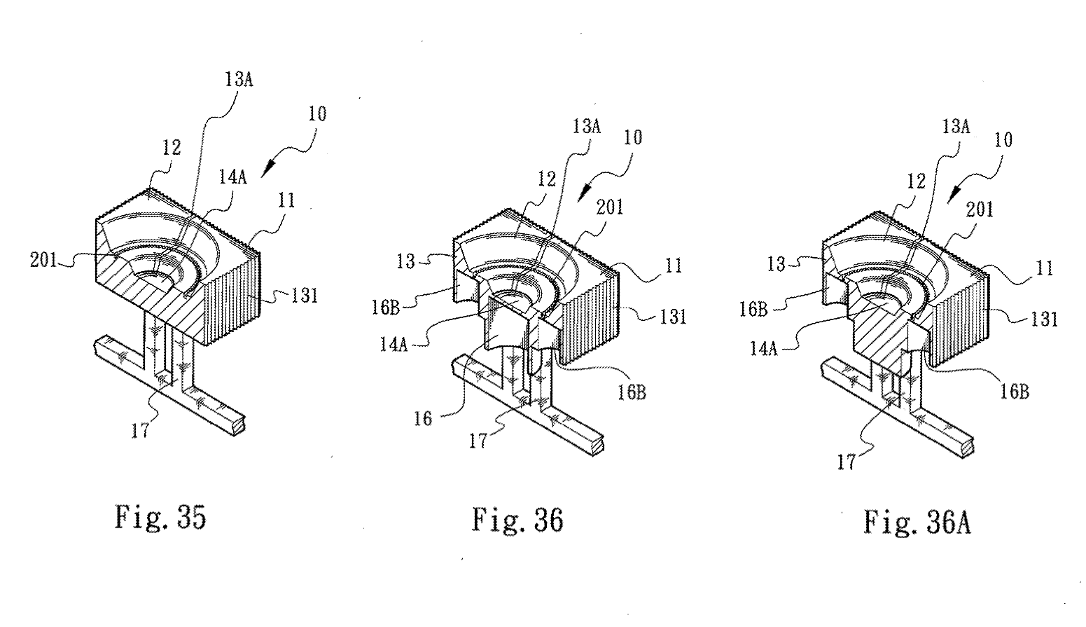

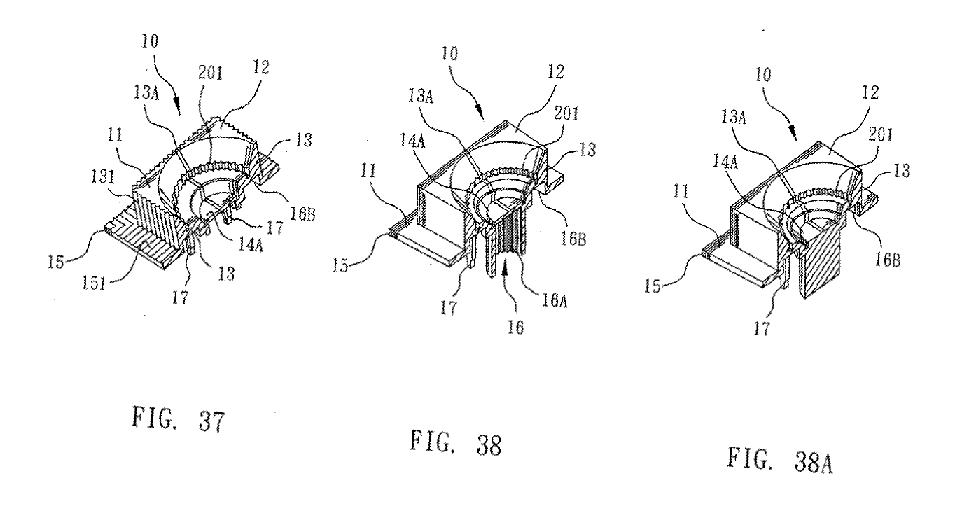

FIGS. 26 to 40 show another modified embodiment according to FIG. 25. In this embodiment, an annular groove 201 is formed on an adjoining portion between two steps of the multistepped cup seat 14A. When packaging the chip 30 and filling the packaging material, due to the surface tension of the material itself and by means of the arrangement of the multistepped cup seat 14A and the grooves 131, the packaging structure and the model body 10 can be more firmly bonded. Also, due to the surface tension and by means of controlling the amount of the packaging material, a transparent packaging body 20 (as shown in FIGS. 29 and 32) with minimized packaging area is formed so as to save cost. In addition, the wall faces of the annular groove 201 can be further formed with continuous saw-toothed structures so as to make the packaging structure more rigid. In a modified embodiment, the bottom of the model body 10 is formed with upward extending grooves 16A and cavities 16B around the cavity 16 at the center of the model body 10. This increases the heat-dissipating area of the bottom face of the model body 10 as shown in FIG. 38.

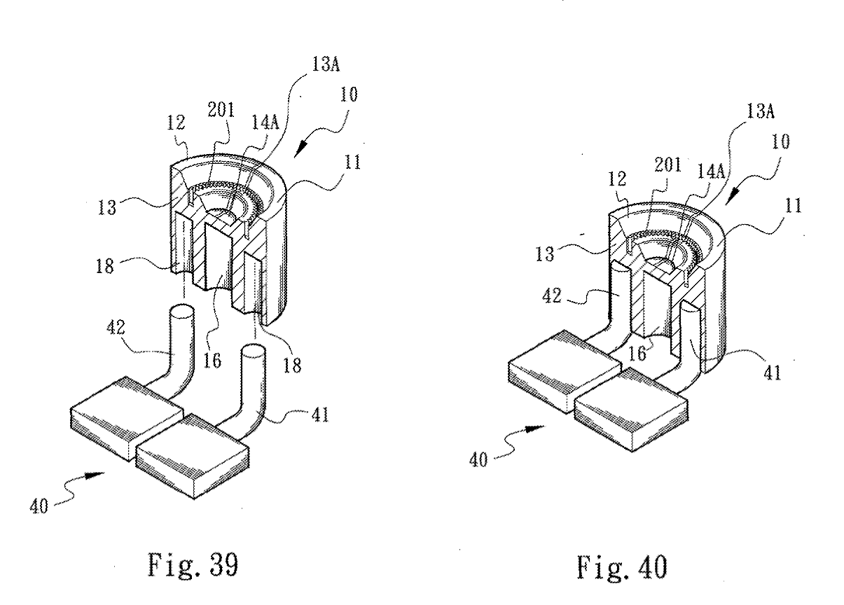

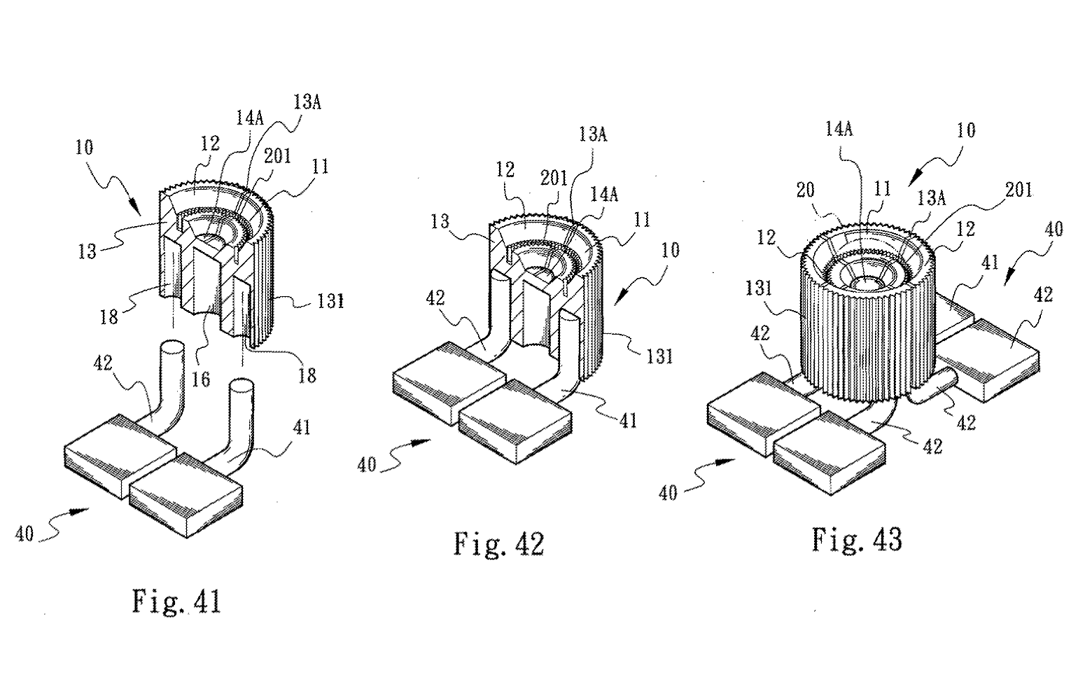

FIGS. 39 to 43 show a modification of the embodiment of FIG. 27. In this embodiment, external contact pins 40 are arranged on outer side of the model body 10. The bottom face of the model body 10 is formed with at least one socket 18. An electroconductive layer 11 or 12 is disposed on the inner wall face of the socket 18. The cathode contact pin 41 and the anode contact pin 42 of the external contact pins 40 are inserted into the sockets 18, the external contact pins 40 are electrically connected with the light-emitting chip 30. In another preferred embodiment, the sockets 18 are arranged on a predetermined section of the model body 10 in accordance with the layout of the electroconductive layers 11, 12 as shown in FIG. 45.

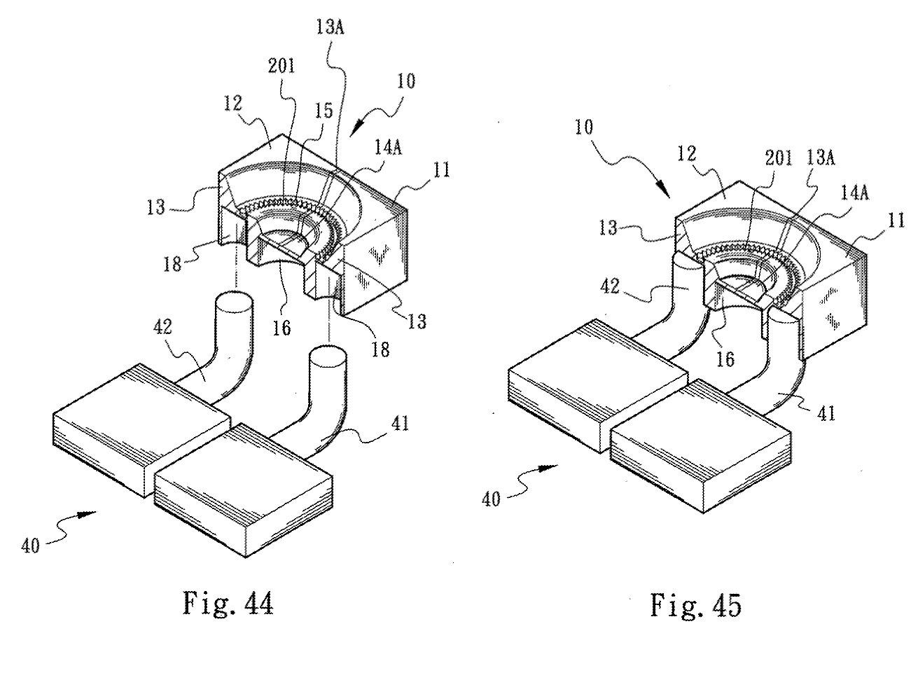

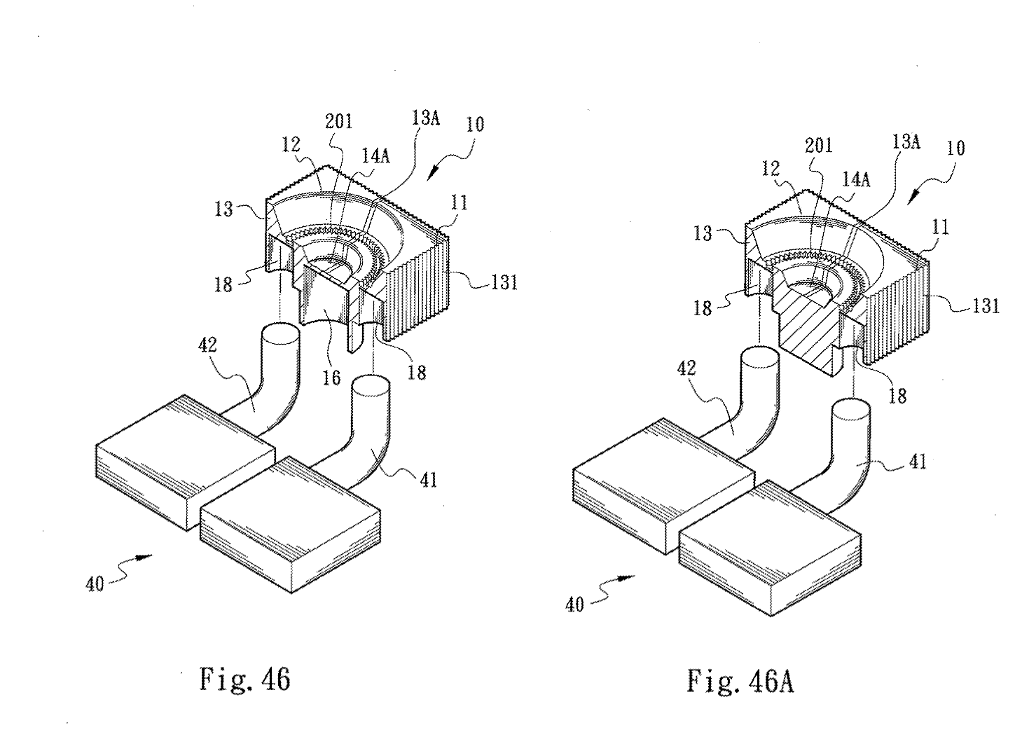

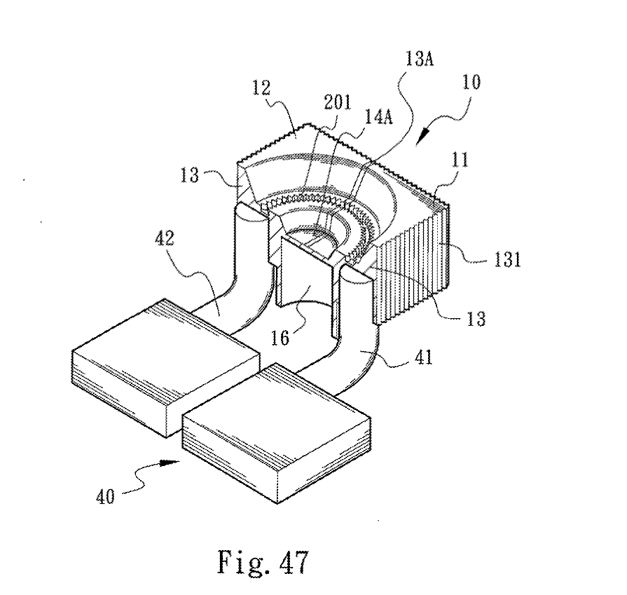

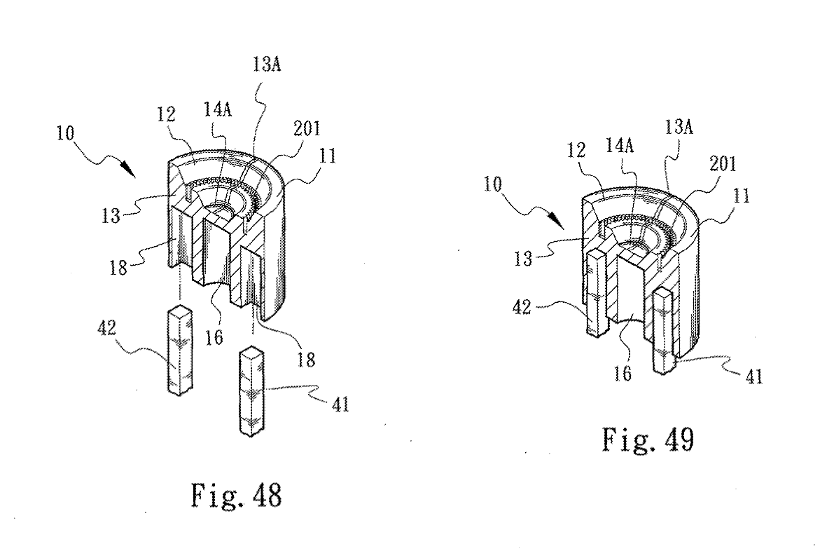

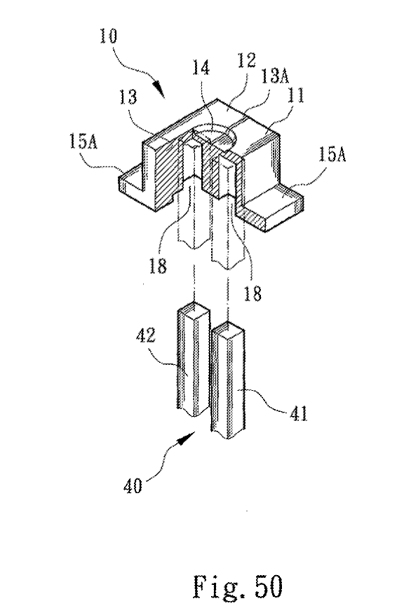

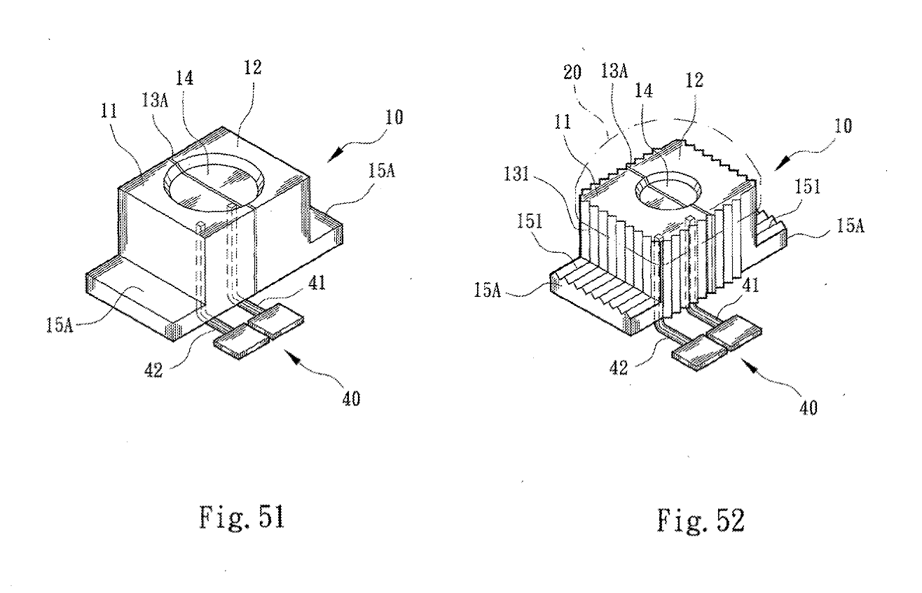

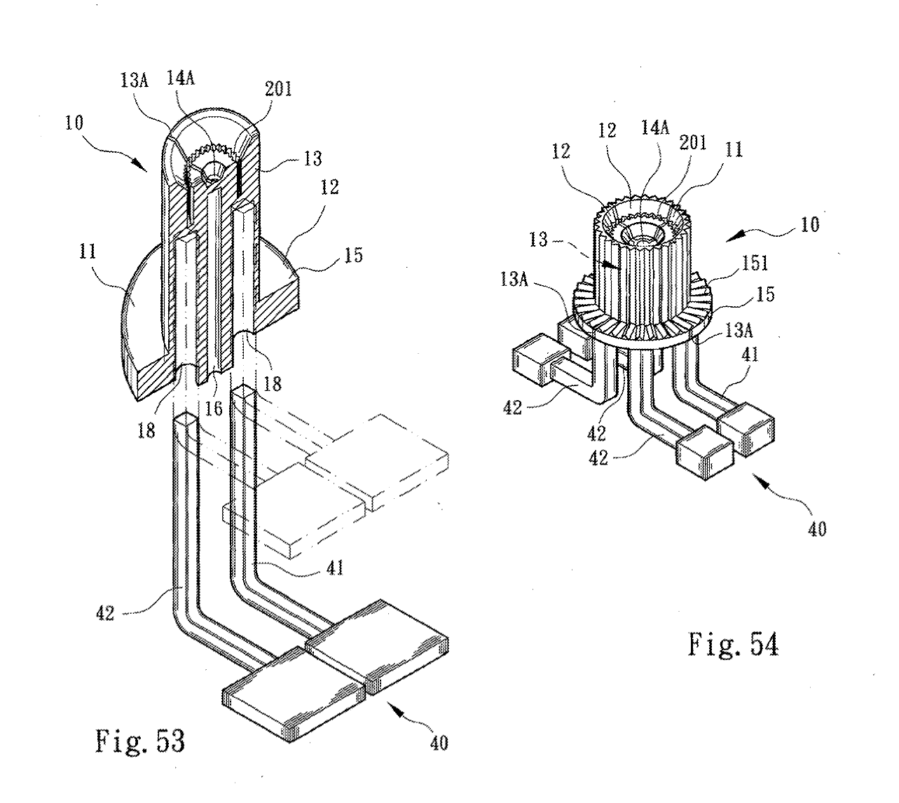

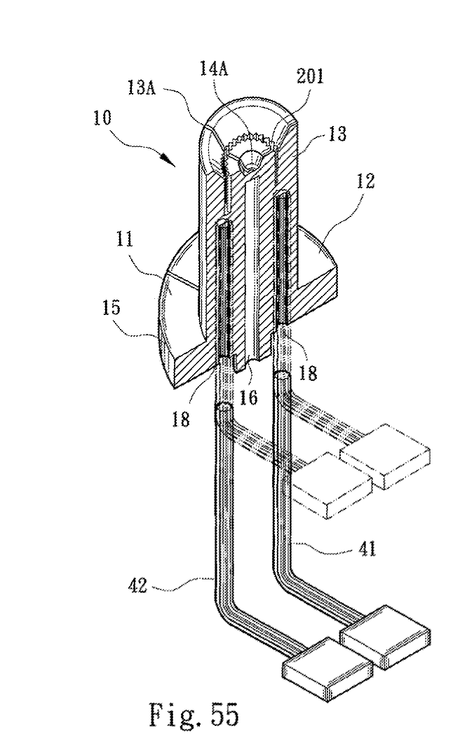

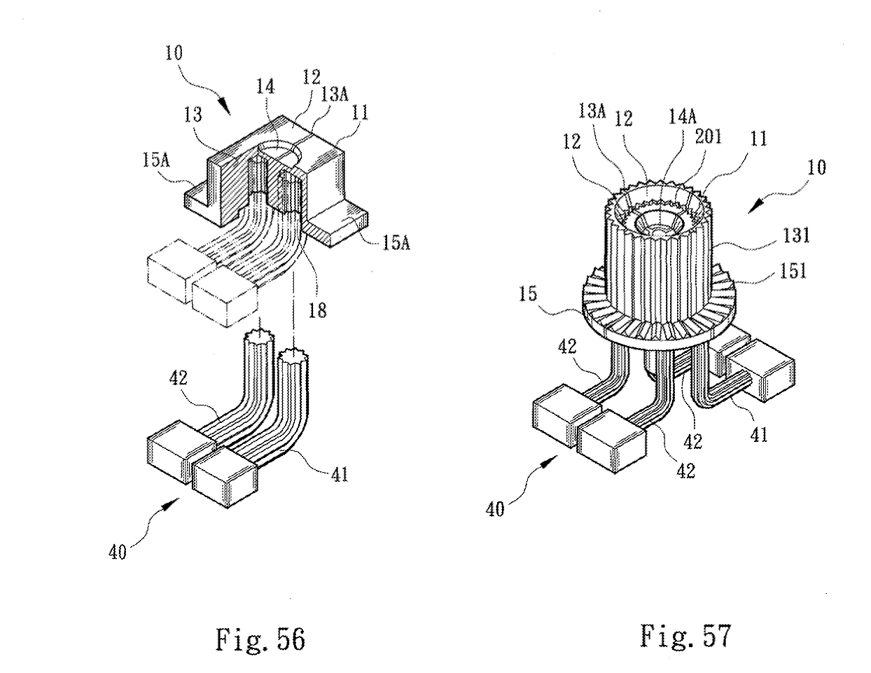

In FIGS. 44 to 47, the model body 10 is a rectangular solid body. In FIGS. 48 to 54, the external contact pins 40 are rectangular solid bodies applied to circular and rectangular model bodies 10. In FIGS. 55 to 57, the external contact pins 40 have a splined structure applied to circular and rectangular model bodies 10.

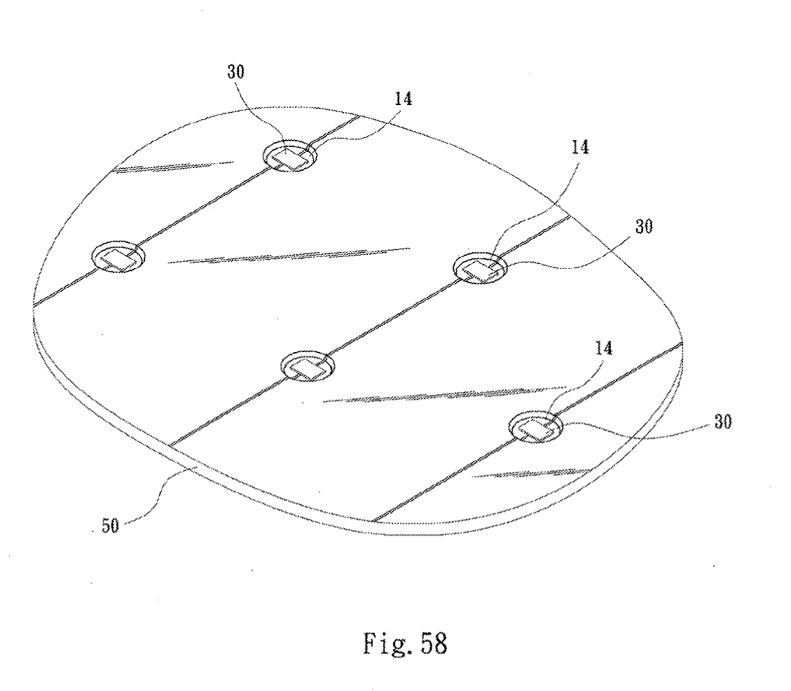

Referring to FIG. 58, several cup seats 14 can be integrally arranged on a board unit 50 in array or not in array. Accordingly, multiple light-emitting chips can be disposed in the cup seats 14 to widen the application range and lower the manufacturing cost.

In conclusion, the chip seat structure for light-emitting crystal of the present invention is different from the conventional chip seat. The model body 10 of the chip seat of the present invention is integrally made of a thermoconductive nonelectroconductive material to form a thermoconductive section. The electroconductive layers are respectively built on the thermoconductive section to serve as the cathode and anode which are separated by an electrode-separating line. The chip seat of the present invention has better heat-dissipating efficiency and larger area of the cup seat. Accordingly, more light-emitting chips with higher power can be arranged on the model body.

The above embodiments are only used to illustrate the present invention, not intended to limit the scope thereof. Many modifications of the above embodiments can be made without departing from the spirit of the present invention.

What is claimed is:

1. A chip seat structure for light-emitting crystal, comprising:
a model body made of a thermoconductive nonelectroconductive material, the model body having an integrated thermoconductive section; at least one cup seat disposed on a top face of the model body for mounting at least one light-emitting chip therein; and multiple electroconductive layers built on the surfaces of the model body and the cup seat, the electroconductive layers being designed with at least two electroconductive regions respectively defined as a cathode and an anode, at least one electrode-separating line being laid between the two electroconductive regions as a separating region.

2. The chip seat structure for light-emitting crystal as claimed in claim 1, wherein the electroconductive layers are spread from the cup seat to a surface of the model body outside the cup seat.

3. The chip seat structure for light-emitting crystal as claimed in claim 1 wherein the surface of the model body is formed with multiple grooves for enlarging the contact area between the model body and the outer side.

4. The chip seat structure for light-emitting crystal as claimed in claim 2, wherein the surface of the model body is formed with multiple grooves for enlarging the contact area between the model body and the outer side.

5. The chip seat structure for light-emitting crystal as claimed in claim 1, wherein the bottom of the model body is formed with at least one cavity upward extending from the bottom face of the model body.

6. The chip seat structure for light-emitting crystal as claimed in claim 2, wherein the bottom of the model body is formed with at least one cavity upward extending from the bottom face of the model body.

7. The chip seat structure for light-emitting crystal as claimed in claim 3, wherein the bottom of the model body is formed with at least one cavity upward extending from the bottom face of the model body.

8. The chip seat structure for light-emitting crystal as claimed in claim 4, wherein the bottom of the model body is formed with at least one cavity upward extending from the bottom face of the model body.

9. The chip seat structure for light-emitting crystal as claimed in claim 5, wherein inner wall faces of the cavity are formed with grooves.

10. The chip seat structure for light-emitting crystal as claimed in claim 6, wherein inner wall faces of the cavity are formed with grooves.

11. The chip seat structure for light-emitting crystal as claimed in claim 7, wherein inner wall faces of the cavity are formed with grooves.

12. The chip seat structure for light-emitting crystal as claimed in claim 8, wherein inner wall faces of the cavity are formed with grooves.

13. The chip seat structure for light-emitting crystal as claimed in claim 1, wherein the model body has a flange section.

14. The chip seat structure for light-emitting crystal as claimed in claim 2, wherein the model body has a flange section.

15. The chip seat structure for light-emitting crystal as claimed in claim 3, herein the model body has a flange section.

16. The chip seat structure for light-emitting crystal as claimed in claim 4, wherein the model body has a flange section.

17. The chip seat structure for light-emitting crystal as claimed in claim 5, wherein the model body has a flange section.

18. The chip seat structure for light-emitting crystal as claimed in claim 9, wherein the model body has a flange section.

19. The chip seat structure for light-emitting crystal as claimed in claim 1, wherein the model body has a wing section.

20. The chip seat structure for light-emitting crystal as claimed in claim 2, wherein the model body has a wing section.

21. The chip seat structure for light-emitting crystal as claimed in claim 3, wherein the model body has a wing section.

22. The chip seat structure for light-emitting crystal as claimed in claim 4, wherein the model body has a wing section.

23. The chip seat structure for light-emitting crystal as claimed in claim 5, wherein the model body has a wing section.

24. The chip seat structure for light-emitting crystal as claimed in claim 9, wherein the model body has a wing section.

25. The chip seat structure for light-emitting crystal as claimed in claim 1, wherein at least one contact pin is inlaid in the thermoconductive section of the model body.

26. The chip seat structure for light-emitting crystal as claimed in claim 2, wherein at least one contact pin is inlaid in the thermoconductive section of the model body.

27. The chip seat structure for light-emitting crystal as claimed in claim 3, wherein at least one contact pin is inlaid in the thermoconductive section of the model body.

28. The chip seat structure for light-emitting crystal as claimed in claim 4, wherein at least one contact pin is inlaid in the thermoconductive section of the model body.

29. The chip seat structure for light-emitting crystal as claimed in claim 5, wherein at least one contact pin is inlaid in the thermoconductive section of the model body.

30. The chip seat structure for light-emitting crystal as claimed in claim 9, wherein at least one contact pin is inlaid in the thermoconductive section of the model body.

31. The chip seat structure for light-emitting crystal as claimed in claim 13, wherein at least one contact pin is inlaid in the thermoconductive section of the model body.

32. The chip seat structure for light-emitting crystal as claimed in claim 19, wherein at least one contact pin is inlaid in the thermoconductive section of the model body.

33. The chip seat structure for light-emitting crystal as claimed in claim 1, wherein the model body is formed with at least one socket.

34. The chip seat structure for light-emitting crystal as claimed in claim 2, wherein the model body is formed with at least one socket.

35. The chip seat structure for light-emitting crystal as claimed in claim 3, wherein the model body is formed with at least one socket.

36. The chip seat structure for light-emitting crystal as claimed in claim 4, wherein the model body is formed with at least one socket.

37. The chip seat structure for light-emitting crystal as claimed in claim 5, wherein the model body is formed with at least one socket.

38. The chip seat structure for light-emitting crystal as claimed in claim 9, wherein the model body is formed with at least one socket.

39. The chip seat structure for light-emitting crystal as claimed in claim 13, wherein the model body is formed with at least one socket.

40. The chip seat structure for light-emitting crystal as claimed in claim 19, wherein the model body is formed with at least one socket.

41. The chip seat structure for light-emitting crystal as claimed in claim 25, wherein the model body is formed with at least one socket.

42. The chip seat structure for light-emitting crystal as claimed in claim 33, wherein the socket of the model body is for inserting an external electric contact pin therein.

43. The chip seat structure for light-emitting crystal as claimed in claim 34, wherein the socket of the model body is for inserting an external electric contact pin therein.

44. The chip seat structure for light-emitting crystal as claimed in claim 35, wherein the socket of the model body is for inserting an external electric contact pin therein.

45. The chip seat structure for light-emitting crystal as claimed in claim 36, wherein the socket of the model body is for inserting an external electric contact pin therein.

46. The chip seat structure for light-emitting crystal as claimed in claim 37, wherein the socket of the model body is for inserting an external electric contact pin therein.

47. The chip seat structure for light-emitting crystal as claimed in claim 38, wherein the socket of the model body is for inserting an external electric contact pin therein.

48. The chip seat structure for light-emitting crystal as claimed in claim 39, wherein the socket of the model body is for inserting an external electric contact pin therein.

49. The chip seat structure for light-emitting crystal as claimed in claim 40, wherein the socket of the model body is for inserting an external electric contact pin therein.

50. The chip seat structure for light-emitting crystal as claimed in claim 41, wherein the socket of the model body is for inserting an external electric contact pin therein.

51. The chip seat structure for light-emitting crystal as claimed in claim 1, wherein the cup seat is formed with at least one pit in which glue material can be filled for adhering the chip to the cup seat.

52. The chip seat structure for light-emitting crystal as claimed in claim 2, wherein the cup seat is formed with at least one pit in which glue material can be filled for adhering the chip to the cup seat.

53. The chip seat structure for light-emitting crystal as claimed in claim 3, wherein the cup seat is formed with at least one pit in which glue material can be filled for adhering the chip to the cup seat.

54. The chip seat structure for light-emitting crystal as claimed in claim 4, wherein the cup seat is formed with at least one pit in which glue material can be filled for adhering the chip to the cup seat.

55. The chip seat structure for light-emitting crystal as claimed in claim 5, wherein the cup seat is formed with at least one pit in which glue material can be filled for adhering the chip to the cup seat.

56. The chip seat structure for light-emitting crystal as claimed in claim 9, wherein the cup seat is formed with at least one pit in which glue material can be filled for adhering the chip to the cup seat.

57. The chip seat structure for light-emitting crystal as claimed in claim 13, wherein the cup seat is formed with at least one pit in which glue material can be filled for adhering the chip to the cup seat.

58. The chip seat structure for light-emitting crystal as claimed in claim 19, wherein the cup seat is formed with at least one pit in which glue material can be filled for adhering the chip to the cup seat.

59. The chip seat structure for light-emitting crystal as claimed in claim 25, wherein the cup seat is formed with at least one pit in which glue material can be filled for adhering the chip to the cup seat.

60. The chip seat structure for light-emitting crystal as claimed in claim 33, wherein the cup seat is formed with at least one pit in which glue material can be filled for adhering the chip to the cup seat.

61. The chip seat structure for light-emitting crystal as claimed in claim 42, wherein the cup seat is formed with at least one pit in which glue material can be filled for adhering the chip to the cup seat.

62. The chip seat structure for light-emitting crystal as claimed in claim 1, wherein the cup seat is a multistepped cup seat.

63. The chip seat structure for light-emitting crystal as claimed in claim 2, wherein the cup seat is a multistepped cup seat.

64. The chip seat structure for light-emitting crystal as claimed in claim 3, wherein the cup seat is a multistepped cup seat.

65. The chip seat structure for light-emitting crystal as claimed in claim 4, wherein the cup seat is a multistepped cup seat.

66. The chip seat structure for light-emitting crystal as claimed in claim 5, wherein the cup seat is a multistepped cup seat.

67. The chip seat structure for light-emitting crystal as claimed in claim 9, wherein the cup seat is a multistepped cup seat.

68. The chip seat structure for light-emitting crystal as claimed in claim 13, wherein the cup seat is a multistepped cup seat.

69. The chip seat structure for light-emitting crystal as claimed in claim 19, wherein the cup seat is a multistepped cup seat.

70. The chip seat structure for light-emitting crystal as claimed in claim 25, wherein the cup seat is a multistepped cup seat.

71. The chip seat structure for light-emitting crystal as claimed in claim 33, wherein the cup seat is a multistepped cup seat.

72. The chip seat structure for light-emitting crystal as claimed in claim 42, wherein the cup seat is a multistepped cup seat.

73. The chip seat structure for light-emitting crystal as claimed in claim 51, wherein the cup seat is a multistepped cup seat.

74. The chip seat structure for light-emitting crystal as claimed in claim 62, wherein a groove is formed on an adjoining portion between two steps of the multistepped cup seat.

75. The chip seat structure for light-emitting crystal as claimed in claim 63, wherein a groove is formed on an adjoining portion between two steps of the multistepped cup seat.

76. The chip seat structure for light-emitting crystal as claimed in claim 64, wherein a groove is formed on an adjoining portion between two steps of the multistepped cup seat.

77. The chip seat structure for light-emitting crystal as claimed in claim 65, wherein a groove is formed on an adjoining portion between two steps of the multistepped cup seat.

78. The chip seat structure for light-emitting crystal as claimed in claim 66, wherein a groove is formed on an adjoining portion between two steps of the multistepped cup seat.

79. The chip seat structure for light-emitting crystal as claimed in claim 67, wherein a groove is formed on an adjoining portion between two steps of the multi-stepped cup seat.

80. The chip seat structure for light-emitting crystal as claimed in claim 68, wherein a groove is formed on an adjoining portion between two steps of the multistepped cup seat.

81. The chip seat structure for light-emitting crystal as claimed in claim 69, wherein a groove is formed on an adjoining portion between two steps of the multistepped cup seat.

82. The chip seat structure for light-emitting crystal as claimed in claim 70, wherein a groove is formed on an adjoining portion between two steps of the multistepped cup seat.

83. The chip seat structure for light-emitting crystal as claimed in claim 71, wherein a groove is formed on an adjoining portion between two steps of the multistepped cup seat.

84. The chip seat structure for light-emitting crystal as claimed in claim 72, wherein a groove is formed on an adjoining portion between two steps of the multistepped cup seat.

85. The chip seat structure for light-emitting crystal as claimed in claim 73, wherein a groove is formed on an adjoining portion between two steps of the multistepped cup seat.

86. The chip seat structure for light-emitting crystal as claimed in claim 1, wherein the top section of the model body is packaged by a transparent body sufficient to seal the chip, the model body being simply partially packaged with the transparent body.

87. The chip seat structure for light-emitting crystal as claimed in claim 2, wherein the top section of the model body is packaged by a transparent body sufficient to seal the chip, the model body being simply partially packaged with the transparent body.

88. The chip seat structure for light-emitting crystal as claimed in claim 3, wherein the top section of the model body is packaged by a transparent body sufficient to seal the chip, the model body being simply partially packaged with the transparent body.

89. The chip seat structure for light-emitting crystal as claimed in claim 4, wherein the top section of the model body is packaged by a transparent body sufficient to seal the chip, the model body being simply partially packaged with the transparent body.

90. The chip seat structure for light-emitting crystal as claimed in claim 5, wherein the top section of the model body is packaged by a transparent body sufficient to seat he chip, the model body being simply partially packaged with the transparent body.

91. The chip seat structure for light-emitting crystal as claimed in claim 9, where n the top section of the model body is packaged by a transparent body sufficient to seal the chip, the model body being simply partially packaged with the transparent body.

92. The chip seat structure for light-emitting crystal as claimed in claim 13, wherein the top section of the model body is packaged by a transparent body sufficient to seal the chip, the model body being simply partially packaged with the transparent body.

93. The chip seat structure for light-emitting crystal as claimed in claim 19, wherein the top section of the model body is packaged by a transparent body sufficient to seal the chip, the model body being simply partially packaged with the transparent body.

94. The chip seat structure for light-emitting crystal as claimed in claim 25, wherein the top section of the model body is packaged by a transparent body sufficient to seal the chip, the model body being simply partially packaged with the transparent body.

95. The chip seat structure for light-emitting crystal as claimed in claim 33, wherein the top section of the model body is packaged by a transparent body sufficient to seal the chip, the model body being simply partially packaged with the transparent body.

96. The chip seat structure for light-emitting crystal as claimed in claim 42, wherein the top section of the model body is packaged by a transparent body sufficient to seal the chip, the model body being simply partially packaged with the transparent body.

97. The chip seat structure for light-emitting crystal as claimed in claim 51, wherein the top section of the model body is packaged by a transparent body sufficient to seal the chip, the model body being simply partially packaged with the transparent body.

98. The chip seat structure for light-emitting crystal as claimed in claim 62, wherein the top section of the model body is packaged by a transparent body sufficient to seal the chip, the model body being simply partially packaged with the transparent body.

99. The chip seat structure for light-emitting crystal as claimed in claim 74, wherein the top section of the model body is packaged by a transparent body sufficient to seal the chip, the model body being simply partially packaged with the transparent body.

100. The chip seat structure for light-emitting crystal as claimed in claim 86, wherein the transparent body seals the cup seat.

101. The chip seat structure for light-emitting crystal as claimed in claim 87, wherein the transparent body seals the cup seat.

102. The chip seat structure for light-emitting crystal as claimed in claim 88, wherein the transparent body seals the cup seat.

103. The chip seat structure for light-emitting crystal as claimed in claim 89, wherein the transparent body seals the cup seat.

104. The chip seat structure for light-emitting crystal as claimed in claim 90, wherein the transparent body seals the cup seat.

105. The chip seat structure for light-emitting crystal as claimed in claim 91, wherein the transparent body seals the cup seat.

106. The chip seat structure for light-emitting crystal as claimed in claim 92, wherein the transparent body seals the cup seat.

107. The chip seat Structure for light-emitting crystal as claimed in claim 93, wherein the transparent body seals the cup seat.

108. The chip seat structure for light-emitting crystal as claimed in claim 94, wherein the transparent body seals the cup seat.

109. The chip seat structure for light-emitting crystal as claimed in claim 95, wherein the transparent body seals the cup seat.

110. The chip seat structure for light-emitting crystal as claimed in claim 96, wherein the transparent body seals the cup seat.

111. The chip seat structure for light-emitting crystal as claimed in claim 97, wherein the transparent body seals the cup seat.

112. The chip seat structure for light-emitting crystal as claimed in claim 98, wherein the transparent body seals the cup seat.

113. The chip seat structure for light-emitting crystal as claimed in claim 99, wherein the transparent body seals the cup seat.

114. The chip seat structure for light-emitting crystal as claimed in claim 1, wherein multiple cup seats are arranged on one single board unit.

115. The chip seat structure for light-emitting crystal as claimed in claim 2, wherein multiple cup seats are arranged on one single board unit.

116. The chip seat structure for light-emitting crystal as claimed in claim 3, wherein multiple cup seats are arranged on one single board unit.

117. The chip seat structure for light-emitting crystal as claimed in claim 4, wherein multiple cup seats are arranged on one single board unit.

118. The chip seat structure for light-emitting crystal as claimed in claim 5, wherein multiple cup seats are arranged on one single board unit.

119. The chip seat structure for light-emitting crystal as claimed in claim 9, wherein multiple cup seats are arranged on one single board unit.

120. The chip seat structure for light-emitting crystal as claimed in claim 13, wherein multiple cup seats are arranged on one single board unit.

121. The chip seat structure for light-emitting crystal as claimed in claim 25, wherein multiple cup seats are arranged on one single board unit.

122. The chip seat structure for light-emitting crystal as claimed in claim 33, wherein multiple cup seats are arranged on one single board unit.

123. The chip seat structure for light-emitting crystal as claimed in claim 42, wherein multiple cup seats are arranged on one single board unit.

124. The chip seat structure for light-emitting crystal as claimed in claim 51, wherein multiple cup seats are arranged on one single board unit.

125. The chip seat structure for light-emitting crystal as claimed in claim 62, wherein multiple cup seats are arranged on one single board unit.

126. The chip seat structure for light-emitting crystal as claimed in claim 74, wherein multiple cup seats are arranged on one single board unit.

127. The chip seat structure for light-emitting crystal as claimed in claim 86, wherein multiple cup seats are arranged on one single board unit.

128. The chip seat structure for light-emitting crystal as claimed in claim 100, wherein multiple cup seats are arranged on one single board unit.
